(19) United States
(12) Patent Application Publication
(10) Pub. No.: US 2005/0196971 A1
(43) Pub. Date: Sep. 8, 2005

(54) Hardware development to reduce bevel deposition

(75) Inventors: Soovo Sen, Sunnyvale, CA (US); Mark A. Fodor, Redwood City, CA (US); Visweswaren Sivaramakrishnan, Santa Clara, CA (US); Junting Liu, San Jose, CA (US)

Correspondence Address: Patent Counsel, M/S 2061;APPLIED MATERIALS, INC., Legal Affairs Department, P.O. Box 450A, Santa Clara, CA, 95052, US

(73) Assignee: Applied Materials, Inc., Santa Clara, CA (US)

(21) Appl. No.: 11/043,724

(22) Filed: Jan. 26, 2005

Related U.S. Application Data
(60) Provisional application No. 60/550,530, filed on Mar. 5, 2004.
(60) Provisional application No. 60/575,621, filed on May 27, 2004.

(51) Int. Cl. H01L 21/76; H01L 21/31; H01L 21/469

(52) U.S. Cl. 438/778

(57) ABSTRACT

Embodiments in accordance with the present invention relate to various techniques which may be employed alone or in combination, to reduce or eliminate the deposition of material on the bevel of a semiconductor workpiece. In one approach, a shadow ring overlies the edge of the substrate to impede the flow of gases to bevel regions. The geometric feature at the edge of the shadow ring directs the flow of gases toward the wafer in order to maintain thickness uniformity across the wafer while shadowing the edge. In another approach, a substrate heater/support is configured to flow purge gases to the edge of a substrate being supported. These purge gases prevent process gases from reaching the substrate edge and depositing material on bevel regions.

### CROSS-REFERENCE TO RELATED APPLICATION

This nonprovisional patent application claims priority from U.S. provisional patent application No. 60/550,530, filed Mar. 5, 2004, and from U.S. provisional patent application No. 60/575,621, filed May 27, 2004, both of which are incorporated by reference in their entirety herein for all purposes.

### BACKGROUND OF THE INVENTION

Integrated circuits (IC) are manufactured by forming discrete semiconductor devices on a surface of a semiconductor substrate. An example of such a substrate is a silicon (Si) or silicon dioxide (SiO₂) wafer. Semiconductor devices are oftentimes manufactured on very large scales where thousands of micro-electronic devices (e.g., transistors, capacitors, and the like) are formed on a single substrate.

To interconnect the devices on a substrate, a multi-level network of interconnect structures is formed. Material is deposited on the substrate in layers and selectively removed in a series of controlled steps. In this way, various conductive layers are interconnected to one another to facilitate propagation of electronic signals.

One manner of depositing films in the semiconductor industry is known as chemical vapor deposition, or “CVD.” CVD may be used to deposit films of various kinds, including intrinsic and doped amorphous silicon, silicon oxide, silicon nitride, silicon oxynitride and the like. Semiconductor CVD processing is generally done in a vacuum chamber by heating precursor gases which dissociate and react to form the desired film. In order to deposit films at low temperatures and relatively high deposition rates, a plasma can be formed from the precursor gases in the chamber during deposition. Such processes are known as plasma enhanced chemical vapor deposition, or “PECVD.”

Accurate reproducibility of substrate processing is an important factor for improving productivity when fabricating integrated circuits. Precise control of various process parameters is required for achieving consistent results across a substrate, as well as the results that are reproducible from substrate to substrate. More particularly, uniformity of deposited material layers is one of requirements for achieving good manufacturing yield.

In a CVD processing chamber, the substrate is typically disposed on a heated substrate support during processing. The substrate support generally includes embedded electric heating elements for controlling the temperature of the substrate. The substrate support may additionally include channels and grooves for a gas (e.g., helium (He), argon (Ar), and the like) to facilitate the transfer the heat between the substrate support and the substrate. Additionally, the substrate heater assembly may also comprise embedded radio-frequency (RF) electrodes for applying RF bias to the substrate during various plasma enhanced processes.

During a deposition process (e.g., chemical vapor deposition (CVD), plasma enhanced CVD (PECVD), and the like), central and peripheral regions of the substrate are exposed to different processing conditions. Differences in the processing conditions generally result in the low uniformity for the deposited layers. For example, substrates processed on conventional heated substrate supports often allow deposition to occur right up to the substrate's edge, and may also have greater thickness of a deposited layer near the edge of the substrate relative to material deposited in the center of the substrate. Non-uniformity of the deposited layers limits yield and productivity of the deposition process, as well as overall performance of the integrated circuits. Additionally, deposited material along the edge of the substrate may be problematic to correctly positioning substrates on robotic transfer mechanisms. If the substrate is not held in a predefined position on the robotic transfer mechanism, the substrate may become damaged or dropped during transfer, or become misaligned when placed in processing equipment resulting in poor processing results.

Therefore, there is a need in the art for a substrate heater assembly for facilitating deposition of uniform material layers on the substrates without depositing material along the substrate's edge during fabrication of integrated circuits in a semiconductor substrate processing system.

### SUMMARY OF THE INVENTION

Embodiments in accordance with the present invention relate to various techniques which may be employed alone or in combination, to reduce the deposition of material on the bevel of a semiconductor workpiece. In one approach, a shadow ring overlies the edge of the substrate to impede the flow of gases to bevel regions. An inclined geometric feature at the edge of the shadow ring directs the flow of gases toward the wafer in order to maintain thickness uniformity across the wafer while shadowing the edge. In another approach, a substrate heater/support is configured to flow purge gases to the edge of a substrate being supported. These purge gases prevent process gases from reaching the substrate edge and depositing material on bevel regions.

An embodiment of a method in accordance with the present invention for chemical vapor depositing a material upon a workpiece, comprises, positioning a shadow ring featuring an inclined overhang portion overlying edge regions of a substrate supported within a processing chamber, the shadow ring extending a distance of between about 0.8-2.0 mm over the edge regions and separated from the edge regions by a gap of about 0.0045″+/−0.003″. A processing gas is flowed to the chamber, and energy is applied to the chamber to generate a plasma therein, such that reaction of the processing gases results in deposition of a material outside the edge regions.

An alternative embodiment of a method in accordance with the present invention for chemical vapor depositing a dielectric film, comprises, positioning a substrate upon a support within a processing chamber, flowing a purge gas through the support to edge regions of the substrate, and flowing a processing gas to the chamber. Energy is applied to the chamber to generate a plasma therein, such that the purge gas flow impedes a flow of processing gas to the edge regions and inhibits deposition of a dielectric material in the edge regions.

An embodiment of an apparatus in accordance with the present invention for depositing dielectric material on a workpiece, comprises, a vertically moveable substrate support positioned within a processing chamber, an energy source configured to apply energy to the processing chamber in order to generate a plasma therein, and a pumping liner defining an exhaust orifice and a vertical channel. A shadow ring comprising an overhang portion is configured to extend a distance of about 0.8-2.0 mm over the edge regions and be separated from the edge regions by a gap of about 0.0045″+/−0.003″ when the substrate support rises to engage the shadow ring.

A further understanding of embodiments in accordance with the present invention can be made by way of reference to the ensuing detailed description taken in conjunction with the accompanying drawings.

### BRIEF DESCRIPTION OF THE DRAWINGS

FIG. 1 provides a top view of an exemplary semiconductor processing system. The processing system includes pairs of deposition chambers that receive the process kits of the present invention.

FIG. 2 provides a cross-sectional view of an illustrative deposition chamber for comparison. The chamber of FIG. 2 is a twin or “tandem” chamber. However, it is understood that the process kits described herein may be used in a single chamber design.

FIG. 3 provides a partial cross-sectional view of a typical chamber body. The chamber body is depicted in a schematic manner for the purpose of demonstrating gas flow paths. Arrows depict primary gas flow and parasitic gas flow paths within the chamber.

FIG. 4 presents a perspective view of a portion of a deposition chamber. A chamber body is provided to define a substrate processing region, and for supporting various liners. A wafer slit valve is seen in the chamber body, providing a wafer pass-through slit.

FIG. 5 shows a cutaway, perspective view of the illustrative deposition chamber of FIG. 4. Visible in FIG. 5 is a top liner, or “pumping liner,” supported by a surrounding C-channel liner.

FIG. 6 shows the chamber body of FIG. 5, highlighting the two exposed areas from the cutaway view. These two cross-sectional areas are designated as area 6A and area 6B.

FIG. 6A provides an enlarged view of cross-sectional area 6A from FIG. 6. Similarly, FIG. 6B provides an enlarged view of cross-sectional area 6B. The top liner and supporting C-channel liner are seen in each figure.

FIG. 7 shows an exploded view of the chamber body portion of FIG. 4. In this view, various liners from a process kit, in one embodiment, can be more clearly identified.

FIG. 8A shows a simplified cross-sectional view of an embodiment of a shadow ring in accordance with the present invention positioned within a pumping liner and in mating engagement with a substrate support.

FIG. 8B shows a simplified cut-away perspective view of the shadow ring of FIG. 8A.

FIG. 8C shows a simplified plan view of the shadow ring of FIG. 8A.

FIG. 8D shows a simplified and enlarged perspective sectional view of the shadow ring of FIG. 8A.

FIGS. 8E-F show simplified plan views illustrating various dimensions of one embodiment of a shadow ring in accordance with the present invention for use in conjunction with a substrate having a diameter of 300 mm.

FIGS. 8G-H show simplified cross-sectional views illustrating other dimensions of the embodiment of the shadow ring shown in FIGS. 8E-F.

FIG. 9A plots mean thickness and uniformity for a fire wafer of a batch of twenty-five wafers processed utilizing the shadow ring of FIGS. 8A-H.

FIG. 9B plots particle contamination adders of two different sizes for the wafer of the batch of FIG. 9A.

FIG. 9C plots thickness of a deposited film versus distance from the center of the wafer of FIG. 9A.

FIGS. 10AA-10EA shows simplified schematic views of shadow rings having different compositions and shapes.

FIGS. 10AB-10EB plot thickness of deposited material versus radial distance for the shadow rings of FIGS. 10AA-EA, respectively.

FIG. 11A shows a simplified cross-sectional view of another alternative embodiment of a shadow ring in accordance with the present invention, positioned within a pumping liner.

FIG. 11B shows a simplified perspective cut-away view of the shadow ring of FIG. 11A.

FIG. 12A shows a simplified cross-sectional view of an alternative embodiment of a shadow ring in accordance with the present invention, positioned within a pumping liner and in mating engagement with a substrate support.

FIG. 12B shows a perspective view of the shadow ring of FIG. 12A.

FIG. 12C plots thickness of deposited material versus radial distance for a shadow ring of FIG. 12A.

FIG. 13 shows a simplified cross-sectional view of an alternative embodiment of a shadow ring in accordance with the present invention.

FIG. 14A shows a simplified cross-sectional view of a heater featuring an edge purge gas system in accordance with an embodiment of the present invention.

FIG. 14B shows a simplified enlarged cross-sectional view of the heater of FIG. 14A.

FIG. 14C plots deposited film thickness versus position for a substrate featuring a flow of nitrogen edge purge gas.

FIG. 14D plots deposited film thickness versus position for a substrate featuring a flow of helium purge gas.

FIGS. 15A-F show simplified cross-sectional views of process steps for forming polysilicon features on a substrate.

FIGS. 15BA-DA and 15FA show cross-sectional electron micrographs of the respective steps for forming the polysilicon features.

### DESCRIPTION OF THE SPECIFIC EMBODIMENTS

The reliable formation of high aspect ratio features with desired critical dimensions requires precise patterning and subsequent etching of the substrate. A technique sometimes used to form more precise patterns on substrates is photolithography. The technique generally involves the direction of light energy through a lens, or “reticle,” and onto the substrate.

In conventional photolithographic processes, a photoresist material is first applied on a substrate layer to be etched. In the context of optical resists, the resist material is sensitive to radiation or “light energy,” such as ultraviolet or laser sources. The resist material preferably defines a polymer that is tuned to respond to the specific wavelength of light used, or to different exposing sources.

After the resist is deposited onto the substrate, the light source is actuated to emit ultraviolet (UV) light or low X-ray light, for example, directed at the resist-covered substrate. The selected light source chemically alters the composition of the photoresist material. However, the photoresist layer is only selectively exposed. In this respect, a photomask, or “reticle,” is positioned between the light source and the substrate being processed.

The photomask is patterned to contain the desired configuration of features for the substrate. The patterned photomask allows light energy to pass therethrough in a precise pattern onto the substrate surface. The exposed underlying substrate material may then be etched to form patterned features in the substrate surface while the retained resist material remains as a protective coating for the unexposed underlying substrate material. In this manner, contacts, vias, or interconnects may be precisely formed.

The material underlying the developed photoresist film may comprise various materials, such as silicon dioxide (SiO₂) and carbon-doped silicon oxide. A dielectric anti-reflective coating (DARC) may also underlie the developed photoresist film, and this DARC may comprise silicon oxynitride (SiON) and silicon nitride (Si₃N₄). Hafnium dioxide (HfO₂) may also be present underneath the developed photoresist film.

More recently, an effective carbon-based film has been developed by Applied Materials, Inc. of Santa Clara, Calif. That film is known as Advanced Patterning Film™, or “APF.” APF™ generally comprises films of SiON and amorphous carbon, or “α-carbon.”

Details regarding formation of the APF™ film may be found in U.S. Pat. No. 6,573,030, incorporated by reference herein for all purposes. Details regarding formation of a gate structure of a field effect transistor (FET) utilizing the APF film may be found in published U.S. patent application No. 2004/0058517, incorporated by reference herein for all purposes. Details regarding a process kit for depositing the APF™ film may be found in co-pending U.S. nonprovisional patent application Ser. No. 10/322,228, filed Dec. 17, 2002 and incorporated by reference herein for all purposes.

The amorphous carbon layer is generally deposited by plasma enhanced chemical vapor deposition (PECVD) of a gas mixture comprising a carbon source. The gas mixture may be formed from a carbon source that is a liquid precursor or a gaseous precursor. Preferably, the carbon source is a gaseous hydrocarbon. For example, the carbon source may be propylene (C₃H₆). The injection of C₃H₆ is accompanied by the generation of an RF plasma within the process chamber. The gas mixture may further comprise a carrier gas, such as helium (He) or Argon (Ar). The carbonaceous layer may be deposited to a thickness of between about 100 Å and about 20,000 Å, depending upon the application.

The process of depositing a carbon-based (or “organic”) film such as APF™, carbon-containing silicon oxide, or DARC at high deposition rates, for example deposition rates greater than 2,000 A/min, may result in uneven deposition at the wafer bevel regions as compared with central wafer regions. If not completely removed by subsequent O₂ ashing steps, the additional material at the wafer edges can flake off and give rise to wafer contamination. Accordingly, formation of carbon-containing films such as APF™ by PECVD is preferably accomplished utilizing an embodiment of a shadow ring in accordance with the present invention.

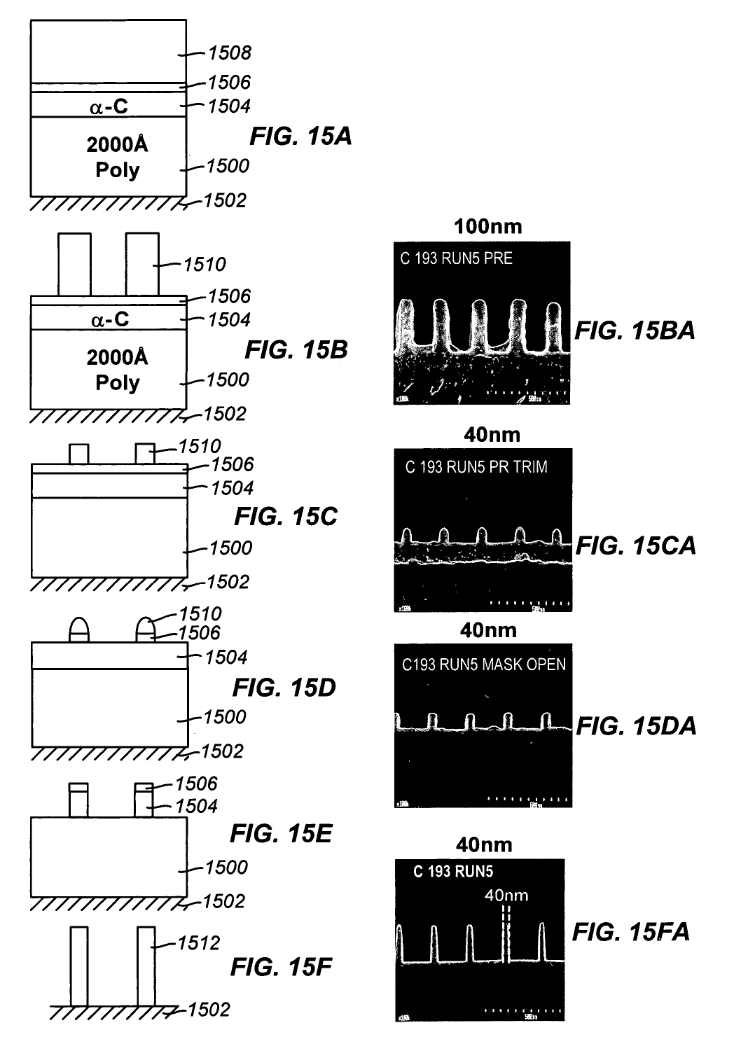

FIGS. 15A-F show simplified cross-sectional views of process steps for forming polysilicon features on a substrate. FIGS. 15BA-FA show cross-sectional electron micrographs of the respective steps for forming the polysilicon features.

As shown in FIG. 15A, a 2000 Å-thick layer of polysilicon 1500 is first deposited over a substrate 1502. As described below, polysilicon layer 1500 is to be patterned into features utilizing lithographic techniques. In expectation of this subsequent lithography process, polysilicon layer 1500 bears an amorphous carbon (\acute{α}-C) layer 1504 and a dielectric anti-reflective coating (DARC) 1506 comprising silicon oxynitride.

Amorphous carbon layer 1504 serves has a hardmask, and may also serve as an anti-reflective coating. DARC 1506 serves to facilitate focusing of light incident during the photolithography process, upon a precise depth of field. Both the \acute{α}-C layer 1504 and the DARC layer 1506 are deposited utilizing chemical vapor deposition techniques. And, as described further below, CVD of both \acute{α}-C layer 1504 and DARC layer 1506 both result in formation of material of additional thickness on wafer bevel regions, which can in turn result in contamination and other issues.

As further shown in FIG. 15A, undeveloped photoresist material 1508 is then spun on over DARC 1506. FIGS. 15B-BA shows the resist exposure and development steps, wherein selected portions of undeveloped photoresist material 1508 are exposed to incident radiation followed by chemical development, resulting in the formation of patterned photoresist 1510.

FIGS. 15C-FA illustrate further steps of the process, wherein the developed photoresist 1510 is trimmed (FIGS. 15C-CA), portions of DARC 1506 not masked by photoresist 1510 are removed (FIGS. 15D-DA), and portions of \acute{α}-C layer 1504 not masked by photoresist 1510 and DARC 1506 are removed (FIG. 15E). FIGS. 15F-FA illustrate the final step in the process, wherein the developed photoresist is removed and portions of the polysilicon layer 1500 not masked by the remaining DARC 1506 and \acute{α}-C layers 1504 are removed to stop on substrate 1502, resulting in formation of polysilicon features 1512.

During initial stage of the process shown and described in connection with FIG. 15A, both the \acute{α}-C layer 1504 and the DARC layer 1506 are created utilizing plasma-assisted CVD techniques. The deposition processes for both these layers results in formation of material of additional thickness on wafer bevel regions. Such material deposited on the wafer bevel can result in contamination and other issues.

Accordingly, embodiments of the present invention relate to techniques which may be employed to reduce or eliminate the deposition of material on the bevel of a semiconductor workpiece. In one approach, a shadow ring overlies the edge of the substrate to impede the flow of gases to bevel regions. An inclined geometric feature on the edge of the shadow ring directs the flow of gases toward the wafer in order to maintain thickness uniformity across the wafer while the wafer edge is shadowed. In another approach, a substrate heater/support is configured to flow purge gases to the edge of a substrate being supported. These purge gases prevent process gases from reaching the substrate edge and depositing material on bevel regions.

Exemplary Processing System

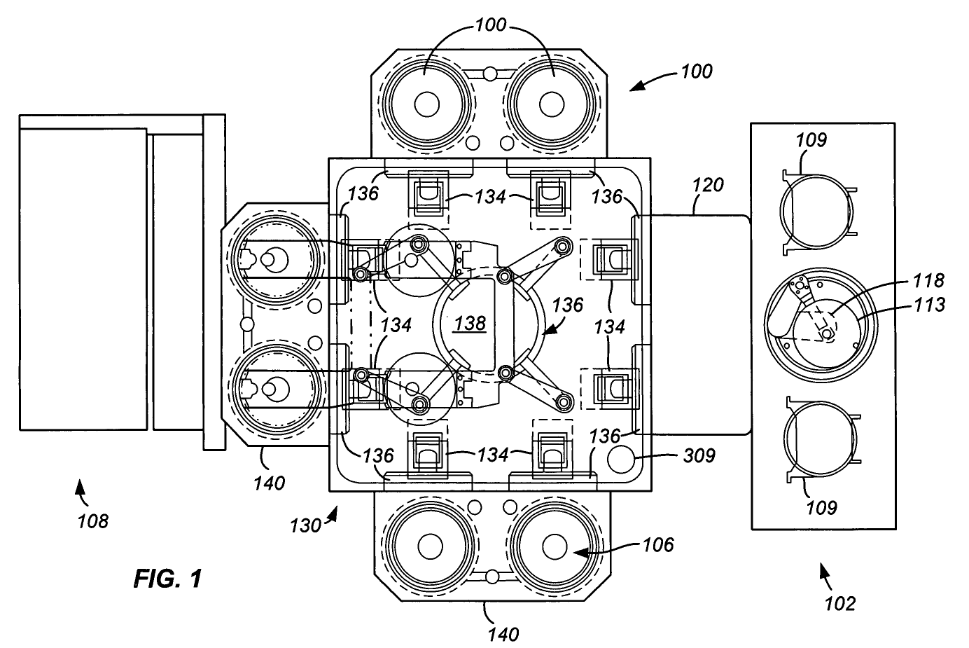

FIG. 1 provides a plan view of an exemplary semiconductor processing system 100. The processing system 100 includes processing chambers 106 that will receive the process kits of the present invention, described below. The illustrative chambers 106 are in pairs to further increase processing throughput.

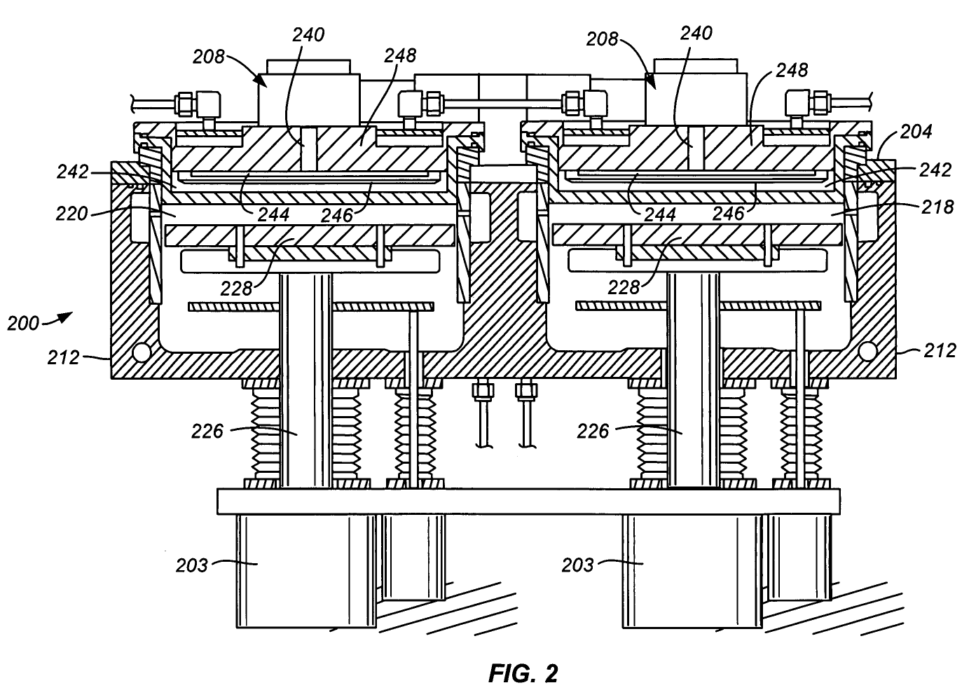

The system 100 generally includes multiple distinct regions. The first region is a front end staging area 102. The front end staging area 102 supports wafer cassettes 109 pending processing. The wafer cassettes 109, in turn, support substrates or wafers 113. A front end wafer handler 118, such as a robot, is mounted on a staging platform adjacent to wafer cassette turntables. Next, the system 100 includes a loadlock chamber 120. Wafers 113 are loaded into and unloaded from the loadlock chamber 120. Preferably, the front end wafer handler 118 includes a wafer mapping system to index the substrates 113 in each wafer cassette 109 in preparation for loading the substrates 113 into a loadlock cassette disposed in the loadlock chamber 120. Next, a transfer chamber 130 is provided. The transfer chamber 130 houses a wafer handler 136 that handles substrates 113 received from the loadlock chamber 120. The wafer handler 136 includes a robot assembly 138 mounted to the bottom of the transfer chamber 130. The wafer handler 136 delivers wafers through sealable passages 136. Slit valve actuators 134 actuate sealing mechanisms for the passages 136. The passages 136 mate with wafer passages 236 in process chambers 140 (shown in FIG. 2) to allow entry of substrates 113 into the processing regions for positioning on a wafer heater pedestal (shown at 228 in FIG. 2).

A back end 150 is provided for housing various support utilities (not shown) needed for operation of the system 100. Examples of such utilities include a gas panel, a power distribution panel, and power generators. The system can be adapted to accommodate various processes and supporting chamber hardware such as CVD, PVD, and etch. The embodiment described below will be directed to a system employing a 300 mm APF deposition chamber. However, it is to be understood that other processes and chamber configurations are contemplated by the present invention.

Exemplary Processing Chamber

FIG. 2 presents a cross-sectional, schematic diagram of a deposition chamber 200 for comparison. The deposition chamber is a CVD chamber for depositing a carbon-based gaseous substance, such as a carbon-doped silicon oxide sublayer. This figure is based upon features of the Producer S® APF chamber currently manufactured by Applied Materials, Inc. The Producer® CVD chamber (200 mm or 300 mm) has two isolated processing regions that may be used to deposit carbon-doped silicon oxides and other materials. A chamber having two isolated processing regions is described in U.S. Pat. No. 5,855,681, which is incorporated by reference herein.

The chamber 200 has a body 202 that defines an inner chamber area. Separate processing regions 218 and 220 are provided Each chamber 218, 220 has a pedestal 228 for supporting a substrate (not seen) within the chamber 200. The pedestal 228 typically includes a heating element (not shown). Preferably, the pedestal 228 is movably disposed in each processing region 218, 220 by a stem 226 which extends through the bottom of the chamber body 202 where it is connected to a drive system 203. Internally movable lift pins (not shown) are preferably provided in the pedestal 228 to engage a lower surface of the substrate. Preferably, a support ring (not shown) is also provided above the pedestal 228. The support ring may be part of a multi-component substrate support assembly that includes a cover ring and a capture ring. The lift pins act on the ring to receive a substrate before processing, or to lift the substrate after deposition for transfer to the next station.

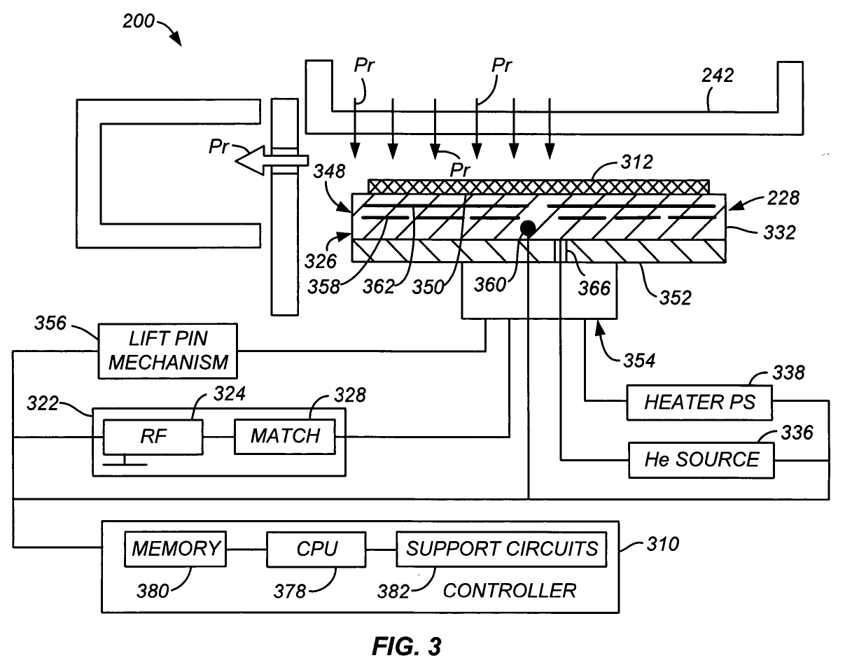

Each of the processing regions 218, 220 also preferably includes a gas distribution assembly 208 disposed through a chamber lid 204 to deliver gases into the processing regions 218, 220. The gas distribution assembly 208 of each processing region normally includes a gas inlet passage 240 which delivers gas into a shower head assembly 242. The showerhead assembly 242 is comprised of an annular base plate 248 having a blocker plate 244 disposed intermediate a face plate 246. The showerhead assembly 242 includes a plurality of nozzles (shown schematically at 248 in FIG. 3) through which gaseous mixtures are injected during processing. The nozzles 248 direct gas, e.g. propylene and argon, downward over a substrate, thereby depositing an amorphous carbon film. An RF (radio frequency) feedthrough provides a bias potential to the showerhead assembly 242 to facilitate generation of a plasma between the face plate 246 of the showerhead assembly 242 and the heater pedestal 228. During a plasma-enhanced chemical vapor deposition process, the pedestal 228 may serve as a cathode for generating the RF bias within the chamber walls 202. The cathode is electrically coupled to an electrode power supply to generate a capacitive electric field in the deposition chamber 200. Typically an RF voltage is applied to the cathode while the chamber body 202 is electrically grounded. Power applied to the pedestal 228 creates a substrate bias in the form of a negative voltage on the upper surface of the substrate. This negative voltage is used to attract ions from the plasma formed in the chamber 200 to the upper surface of the substrate. The capacitive electric field forms a bias which accelerates inductively formed plasma species toward the substrate to provide a more vertically oriented anisotropic filming of the substrate during deposition, and etching of the substrate during cleaning.

FIG. 3 depicts a simplified cross-sectional view of a substrate support of the exemplary Producer® reactor as a process chamber 200. The images in FIG. 3 are simplified for illustrative purposes and are not depicted to scale.

The support pedestal 228 comprises a substrate heater assembly 348, a base plate 352, and a back plane assembly 354. The back plane assembly 354 is coupled to a source 322 of substrate bias power, a controlled heater power supply 338, and a source 336 of a backside gas (e.g., helium (He)), as well as to a lift pin mechanism 356. During substrate processing, the support pedestal 228 supports a substrate 312 and controls the temperature and biasing of the substrate. The substrate 312 is generally a standardized semiconductor wafer, for example a 200 mm or 300 mm wafer.

The substrate heater assembly 348 comprises a body (heater member 332) and heater member 332 further comprises a plurality of embedded heating elements 358, a temperature sensor (e.g., thermocouple) 360, and a plurality of radio-frequency (RF) electrodes 362.

The embedded heating elements 358 are coupled to the heater power supply 338. The temperature sensor 360 monitors, in a conventional manner, the temperature of the heater member 332. The measured temperature is used in a feedback loop to regulate the output of the heater power supply 338.

The embedded RF electrodes 362 couple the source 322 to the substrate 312, as well as to a plasma of the process gas mixture in the reaction volume. The source 322 generally comprises a RF generator 324 and a matching network 328. The generator 324 generally is capable of producing up to 5000 W of continuous or pulsed power at a frequency is a range from about 50 kHz to 13.6 MHz. In other embodiments, the generator 324 may be a pulsed DC power generator.

The temperature of the substrate 312 is controlled by stabilizing a temperature of the heater member 332. In one embodiment, the helium gas from a gas source 336 is provided via a gas conduit 366 to grooves (or, alternatively, positive dimples) 330 (shown using broken lines in FIG. 2 below) formed in the heater member 332 under the substrate 312. The helium gas provides a heat transfer between the heater member 332 and the substrate 312 and facilitates uniform heating of the substrate. Using such thermal control, the substrate 312 may be maintained at a temperature between about 200 and 800° C.

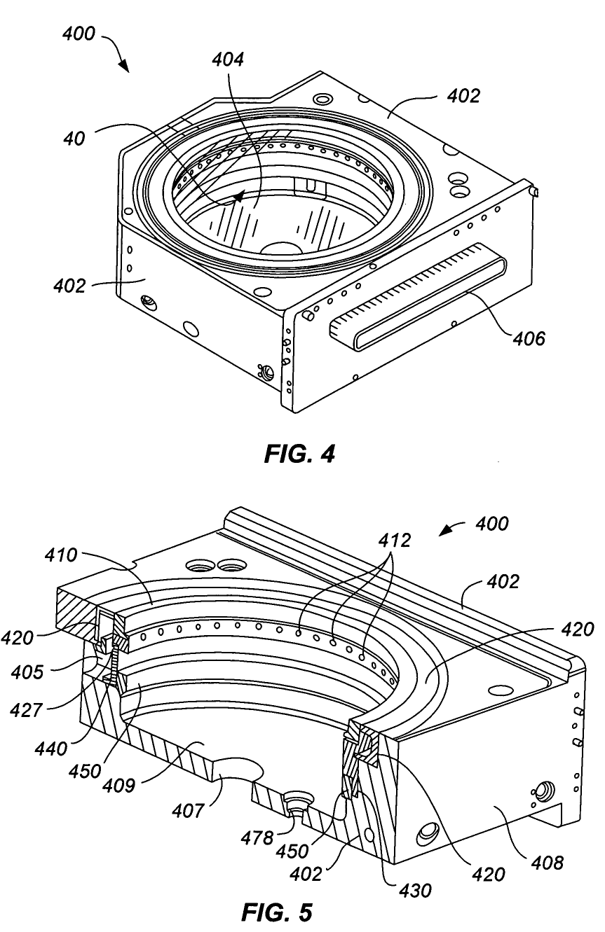

FIG. 4 presents a perspective view of a portion of a deposition chamber 400. The deposition chamber 400 includes a process kit 40 of the present invention, in one embodiment. A chamber body 402 is provided to define a substrate processing region 404, and for supporting various liners of the process kit 40. A wafer slit 406 is seen in the chamber body 402, defining a wafer pass through slit. In this manner, a substrate may be selectively moved into and out of the chamber 400. A substrate is not shown within the hollow chamber. The slit 406 is selectively opened and closed by a gate apparatus (not shown). The gate apparatus is supported by the chamber wall 402. The gate isolates the chamber environment during substrate processing.

The chamber body 402 is preferably fabricated from an aluminum oxide or other ceramic compound. Ceramic material is preferred due to its low thermal conductivity properties. The chamber body 402 may be cylindrical or other shape. The exemplary body 402 of FIG. 4 has an outer polygonal profile, and a circular inner diameter. However, the present invention is not limited to any particular configuration or size of processing chamber.

As noted, the body 402 is configured to support a series of liners and other interchangeable processing parts. These processing parts are generally disposable, and come as part of a “process kit” 40 specific for a particular chamber application or configuration. A process kit may include a top pumping liner, a middle liner, a lower liner, a gas distribution plate, a gas diffuser plate, a heater, a shower head, or other parts. Certain liners may be formed integrally; however, it is preferred in some applications to provide separate liners that are stacked together to allow thermal expansion between the liners. FIG. 7 provides a perspective view of a process kit 40 in one embodiment. The liners and other equipment of the process kit 40 are shown exploded above a deposition chamber 400. The chamber 400 of FIG. 7 will be discussed in greater detail below.

FIG. 5 shows a cutaway, perspective view of the illustrative deposition chamber 400 of FIG. 4. The geometry of the chamber body 402 is more clearly seen, including side 408 and bottom 409 portions of the body 402. An opening 405 is formed in the side portion 408 of the body 402. The opening 405 serves as a channel for receiving process gasses during a deposition, etching or cleaning process.

A substrate is not shown within the hollow chamber 404. However, it is understood that a substrate is supported within the hollow chamber 404 on a pedestal, such as pedestal 228 of FIG. 2. The pedestal is supported by a shaft that extends through opening 407 in the bottom portion 409 of the body 402. In addition, it is understood that a gas processing system (not shown in FIG. 5) is provided for the chamber 400. An opening 478 is provided in the illustrative chamber 400 for receiving a gas conduit. The conduit delivers gas to gas box (seen at 472 in FIG. 7). From there, gas is delivered into the chamber 404.

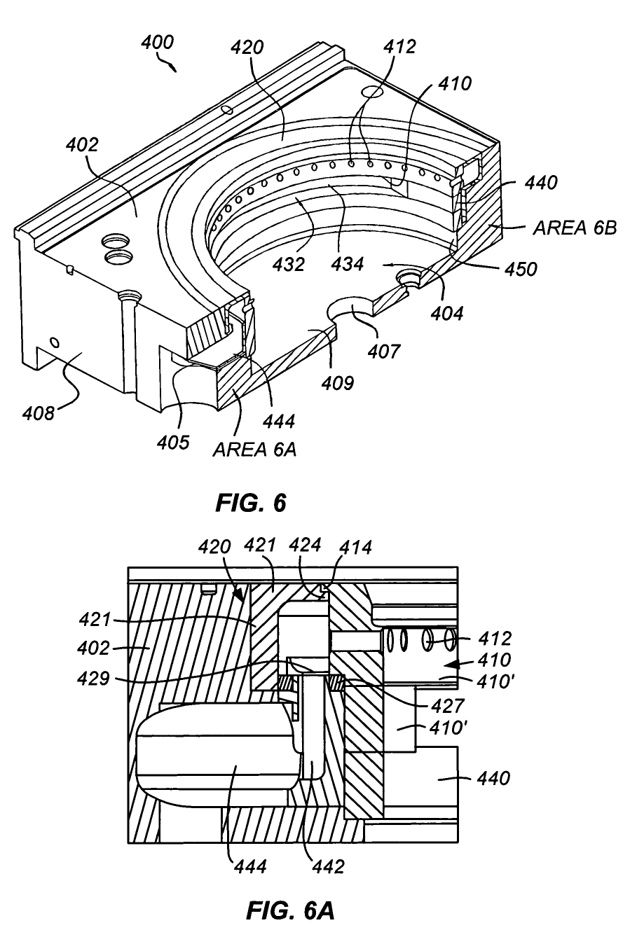

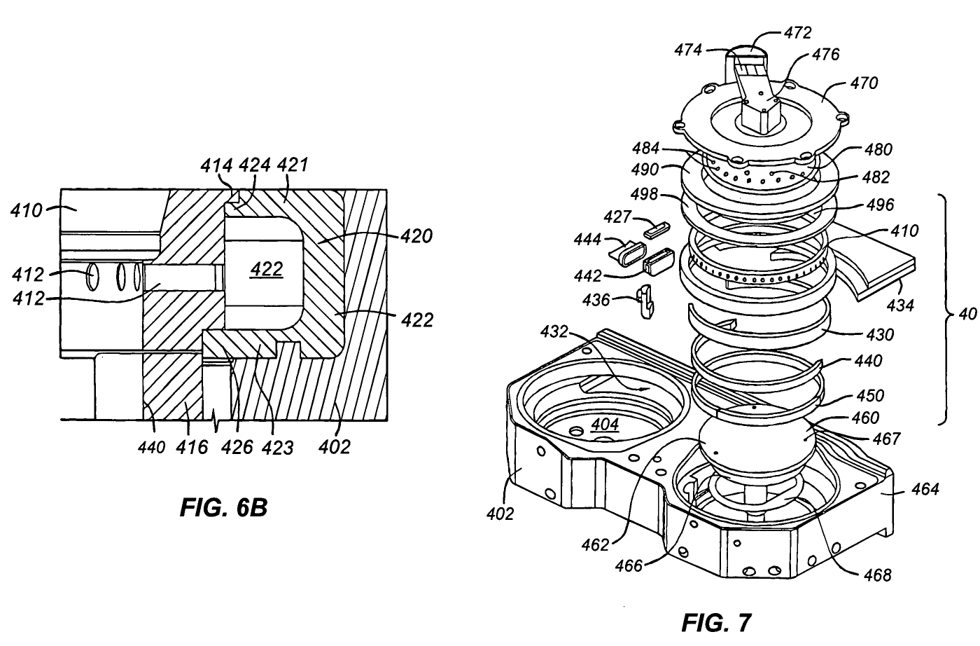

Certain parts of a process kit 40 for a deposition chamber are visible in FIGS. 4 and 5. These include a top pumping liner 410, a supporting C-channel liner 420, a middle liner 440 and a bottom liner 450. As noted, these liners 410, 420, 440 and 450 are shown and will be described in greater detail in connection with FIG. 7, below. A seal member 427 is provided at an interface of the C-channel liner 420 with a pumping port liner 442, and at an interface of the pumping liner 410 with the pumping port liner 442, as will be also shown and described in greater detail in connection with FIG. 6A, below.

FIG. 6 shows another perspective view of the chamber body 402 of FIG. 5. Reference numbers from FIG. 5 are, in some instances repeated. FIG. 6 is provided to highlight the two exposed areas from the cutaway view. These two cross-sectional areas are area 6A and area 6B. Features of the chamber 400 shown in areas 6A and 6B are seen more clearly in the respective enlarged cross-sectional views of FIGS. 6A and 6B. These features will also be described in detail below.

FIG. 7 provides an exploded view of a chamber body portion 400. In this instance, the chamber body 400 represents a tandem processing chamber. An example is the Producer S chamber manufactured by Applied Materials, Inc. Various parts of a process kit 40 are seen arising from processing area 404 on right side of body 402.

The first item of equipment seen in the view of FIG. 7 is a top cover 470. The top cover 470 is centrally located within the processing area 404, and protrudes through the chamber lid (not seen). The top cover 470 serves as a plate to support certain gas delivery equipment. This equipment includes a gas box 472 which receives gas through a gas supply conduit (not seen). (The conduit is inserted through opening 478 in the bottom 409 of the chamber body 402, as seen in FIG. 5). The gas box 472 feeds gas into a gas input 476. The gas input 476 defines an arm that extends over to the center of the top cover 470. In this way, processing and cleaning gases may be introduced centrally into the processing area 404 above the substrate.

An RF power is supplied to the gas box 472. This serves to generate plasma from the processing gases. A constant voltage gradient 474 is disposed between the gas box 472 and the gas input 476. The constant voltage gradient 474, or “CVG,” controls the power level as the gas moves from the gas box 472 towards the grounded pedestal within the processing area 404.

Immediately below the top cover 470 is a blocker plate 480. The blocker plate 480 defines a plate concentrically placed below the top cover 470. The blocker plate 480 includes a plurality of bolt holes 482. The bolt holes 482 serve as a through-opening through which screws or other connectors may be placed for securing the blocker plate 480 to the top cover 470. A spacing is selected between the blocker plate 480 and the top cover 470. Gas is distributed in this spacing during processing, and then delivered through the blocker plate 480 by means of a plurality of perforations 484. In this way, processing gases may be evenly delivered into the processing area 404 of the chamber 400. The blocker plate 480 also provides a high pressure drop for gases as they are diffused.

Below the blocker plate 480 is a shower head 490. The shower head 490 is concentrically placed below the top cover 470. The shower head 490 includes a plurality of nozzles (not seen) for directing gases downward onto the substrate (not seen). A face plate 496 and isolator ring 498 are secured to the shower head 490. The isolator ring 490 electrically isolates the shower head 490 from the chamber body 402. The isolator ring 498 is preferably fabricated from a smooth and relatively heat resistant material, such as Teflon or ceramic.

Disposed below the shower head 490 is a top liner, or “pumping liner” 410. In the embodiment of FIG. 7, the pumping liner 410 defines a circumferential body having a plurality of pumping holes 412 disposed there around. In the arrangement of FIG. 7, the pumping poles 412 are equidistantly spaced apart. During a wafer processing process, a vacuum is pulled from a back side of the top liner 410, drawing gases through the pumping holes 412 and into a channel area 422 (seen more clearly in FIGS. 6A and 6B). The pumping holes 412 provide the primary flow path for processing gases, as depicted in the schematic view of FIG. 3.

Turning to the enlarged cross sectional views of FIGS. 6A and 6B, features of the top liner 410 can be more readily seen. FIG. 6A provides an enlarged view of cross-sectional area 6A from FIG. 6. Similarly, FIG. 6B provides an enlarged view of area 6B from FIG. 6. The pumping liner 410 is visible in each of these enlarged figures.

The pumping liner 410 defines a circumferential body 410′, and serves to hold a plurality of pumping ports 412. In the arrangement of FIG. 7, the pumping liner 410 includes an upper lip 414 on an upper surface area, and a lower shoulder 416 along a lower surface area. In one aspect, the upper lip 414 extends outwardly from the radius of the top liner 410, while the lower shoulder 416 extends radially inward. The upper lip 414 is circumferentially disposed. For this reason, the upper lip 414 is visible in both FIG. 6A and FIG. 6B. However, the lower shoulder 416 does not circumferentially encompass top liner 410, but is left open in the area of upper pumping port liner 442.

Returning to FIG. 4, the chamber 400 next comprises a circumferential channel liner 420. In the arrangement of FIG. 7, the liner 420 has a profile of an inverted “C”. In addition, the liner 420 includes a channel portion 422. For these reasons, the liner 420 is designated as a “C-channel liner.” The inverted “C” configuration is seen more clearly in the enlarged cross sectional view of FIG. 6B.

Looking again at FIG. 6B, the C-channel liner 420 has an upper arm 421, a lower arm 423, and an intermediate inner body 422. The upper arm 421 has an upper shoulder 424 formed therein. The upper shoulder 424 is configured to receive the upper lip 414 of the pumping liner 410. At the same time, the lower arm 423 is configured to receive the lower shoulder 416 of the top liner 410. This interlocking arrangement between the top liner 410 and the C-channel liner 420 provides a circuitous interface that substantially reduces unwanted parasitic pumping. In this way, as gases are exhausted from the processing area 404 of the chamber 400 and through the pumping holes 412 of the pumping liner 410, gas is preferentially evacuated through the channel portion 422 of the C-channel liner 420, and is not lost at the interfaces between the top liner 410 and the

It is to be noted that the interlocking relationship between the upper lip 414 of the pumping liner 410 and the upper shoulder 424 of the C-channel liner 420 is illustrative only. Likewise, the interlocking relationship between the lower shoulder 416 of the pumping liner 410 and the lower lip 426 of the C-channel liner 420 is illustrative only. In this respect, it is within the scope of the present invention to include any interlocking arrangement between the pumping liner 410 and the C-channel liner 420 to inhibit parasitic pumping of processing, cleaning or etch gases. For example, and not by way of limitation, both the upper lip 414 and the lower shoulder 416 of the pumping liner 410 could be configured to extend outwardly from the radius of the top liner 410. In such an arrangement, the lower lip 426 of the C-channel liner 420 would be reconfigured to interlock with the lower shoulder 416 of the pumping liner 410.

In the process kit 40 arrangement of FIGS. 6A, 6B and 7, the upper shoulder 424 is circumferentially disposed along the upper arm 421. For this reason, the upper shoulder 424 is visible in both FIG. 6A and FIG. 6B. However, the lower lip 426 does not circumferentially encompass the C-channel liner 420, but is also left open in the area of the upper pumping port liner 442. Thus, a radial portion is left open to form a pumping port liner opening 429.

As indicated from the cutaway perspective view provided in FIG. 6, areas 6A and 6B show opposite ends of the chamber 400. The cutaway end from area 6A includes gas exhaust ports, referred to as “pumping port liners” 442, 444. An upper pumping port liner 442 is provided below the channel portion 422 of the C-channel liner 420. A lower pumping port liner 444 is then provided in fluid communication with the upper port liner 442. Gas may then be exhausted out of the lower pumping port liner 444 and away from the processing chamber 400 by means of an exhaust system.

To further limit parasitic pumping at the area of the pumping port liners 442, 444, a seal member 427 is provided at the interface between the C-channel liner 420 and the upper pumping port liner 442, and at the interface between the top liner 410 and the upper pumping port liner 442. The seal member is visible at 427 in both FIG. 7 and FIG. 6B. Preferably, the seal member 427 defines a circular ring that encompasses the upper pumping port liner 442. The seal member 427 is preferably fabricated from a Teflon material or otherwise includes a highly polished surface. The seal 427 further enables the C-channel liner 420 to interlock with the pumping ports 442, 444 and to limit gas leakage.

Referring back to FIG. 7, a middle liner 440 is next disposed below the C-channel liner 420. The middle liner 440 resides in the process area 404 at the level of the slit 432. It can be seen from FIG. 7 that the middle liner 440 is a C-shaped liner, and is not circular. The open area in the middle liner 440 is configured to receive wafers as they are imported into the process chamber 400. The middle liner 440 can be partially seen in both FIG. 6A and FIG. 6B, residing below C-channel liner 420 and top liner 410.

Also visible in FIG. 7 is a bottom liner 450. In the arrangement of FIG. 7, the bottom liner 450 is disposed in the chamber 400 below the middle liner 440. The bottom liner 450 resides between middle liner 440 and bottom surface 409 of chamber 400.

It should be noted at this point that it is within the scope of the present invention to utilize a process kit wherein selected liners are integral to one another. For example, the middle liner 440 could be integrally formed with the bottom liner 450. Similarly, the top liner 410 could be integral to the C-channel liner 420. However, it again is preferred that the various liners, e.g., liners 410, 420, 440 and 450 be separate. This substantially reduces the risk of cracking induced by thermal expansion during heating processes. The employment of a separate but interlocking pumping liner 410 and C-channel liner 420 provides an improved and novel arrangement for a process chamber process kit.

Additional process kit items seen in FIG. 7 include a filler member 430 and a pressure equalization port liner 436. The filler member 430 is placed around the middle 440 and bottom 450 liners in order to fill space between the outer diameters of these liners 440, 450 and the surrounding chamber body 402. The presence of the filler member 430 aides in channeling the collection of carbon residues behind the liners 440, 450 by keeping residues from forming behind the liners 440, 450.

It is noted that the filler member 430, like the middle liner 440, is not completely circumferential. In this respect, an open portion is retained in the filler member 430 to provide fluid communication between the two process chambers 404. The pressure equalization port liner 436 controls the fluid communication between the two process areas 404 by defining a sized orifice. The presence of the pressure equalization port liner 436 insures that pressures between the two process areas 404 remain the same.

It is also noted at this point that the filler member 430, the pressure equalization port liner 436, and the upper 442 and lower 444 pumping port liners are preferably coated with a highly smoothed material. An example is a shiny aluminum coating. Other materials provided with a very smooth surface, e.g., less than 15 Ar help reduce deposition accumulating on the surfaces. Such smooth materials may be polished aluminum, polymer coating, Teflon, ceramics and quartz.

To further aide in the reduction of deposition on chamber parts, a slit valve liner 434 is provided along the slit 432. The slit liner 434 is likewise preferably fabricated from a highly smoothed material such as those mentioned above.

It is preferred that during a deposition or etching process, the processing areas 404 be heated. To this end, a heater is provided with the pedestal for supporting wafers. A heater pedestal is seen at 462 in the chamber arrangement 400 of FIG. 7. It is particularly preferred that the heater be actuated to temperatures in excess of 110° C. during a plasma cleaning process. Alternatively, it is possible to use ozone as the cleaning gas, as ozone does not require plasma to disassociate. In instances where ozone is not used, it is particularly desirable to heat the chamber body, thereby increasing the cleaning rate.

Referring again to FIG. 7, a pedestal assembly 460 is provided. The pedestal assembly 460 serves to support a substrate during processing. The pedestal assembly 460 includes not only the heater plate 462, but also a shaft 468, a pin lift 464 and a lift hoop 466 disposed there around. The pin lift 464 and lift hoop 466 aide in selectively raising the wafer above the heater plate 462. Pin holes 467 are disposed within the heater plate 462 to receive lift pins (not shown).

It is understood that the AFP™ chamber 400 of FIG. 7 is illustrative, and that the improvements of the present invention are viable in any deposition chamber capable of performing PECVD. Thus, other embodiments of the inventions may be provided. For example, the pumping liner 410 may have an inner diameter that is smaller than the inner diameter of the C-channel liner 420. This reduced dimension for the top pumping liner 410 serves to reduce the inner diameter of the pumping port 405, thereby increasing velocity of gases moving out of the inner chamber 404 and through the pumping port 405. Increased gas velocity is desirable, as it reduces opportunities for carbonaceous residue buildup on chamber surfaces. It is also desirable that the liners be fabricated from a material having a highly smooth surface. This serves to reduce amorphous carbon deposition from accumulating on the surface. Examples of such material again include polished aluminum, polymer coating, Teflon, ceramics, and quartz.

It is also noted that carbon builds up on colder surfaces faster than on warmer surfaces. Because of this phenomenon, carbon tends to preferentially build up on the pumping system associated with the deposition chamber. The pumping systems are preferably heated to a temperature greater than 80° C. to reduce preferential build-up. Alternatively, or in addition, a cold trap can be integrated into the pumping system to collect unreacted carbon by-product. The cold trap can be cleaned or replaced at regular maintenance intervals.

Shadow Ring

The processing kit described above in FIGS. 1-7 may be modified in accordance with embodiments of the present invention to feature a shadow ring for inhibiting deposition of material on the bevel portion of a semiconductor workpiece.

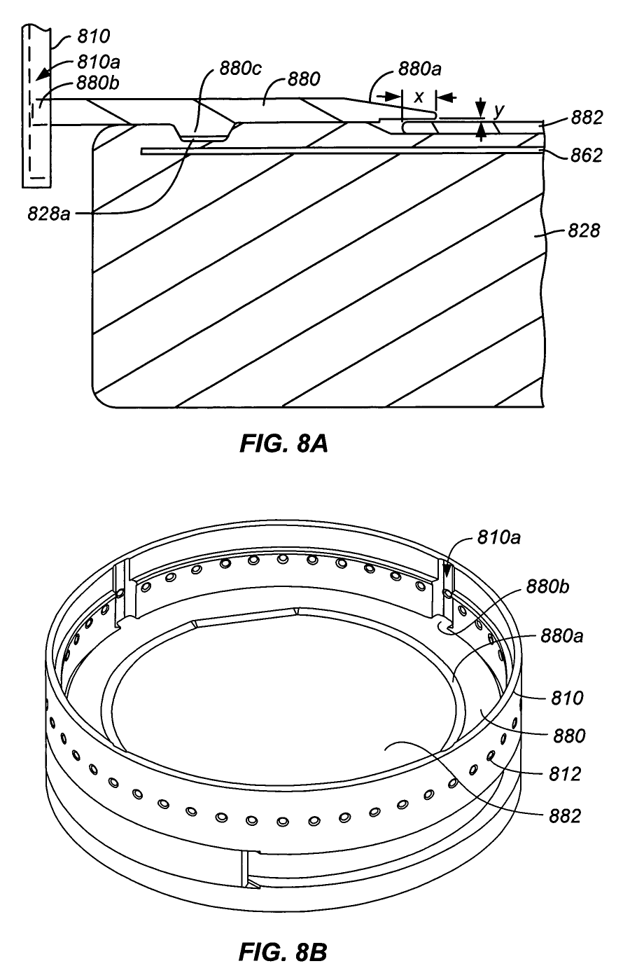

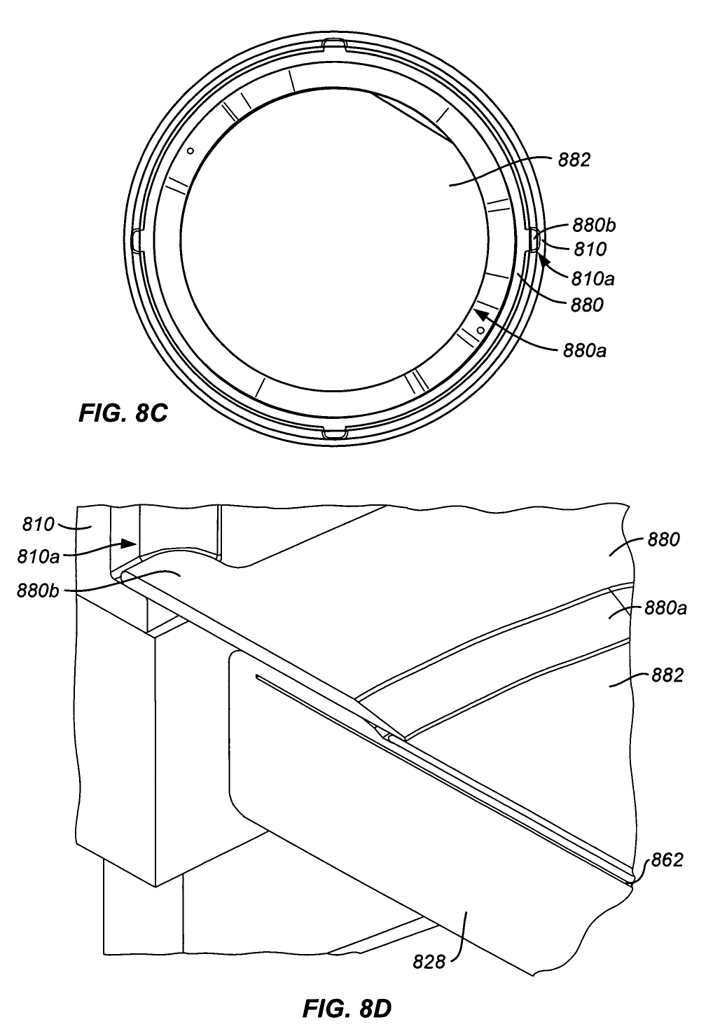

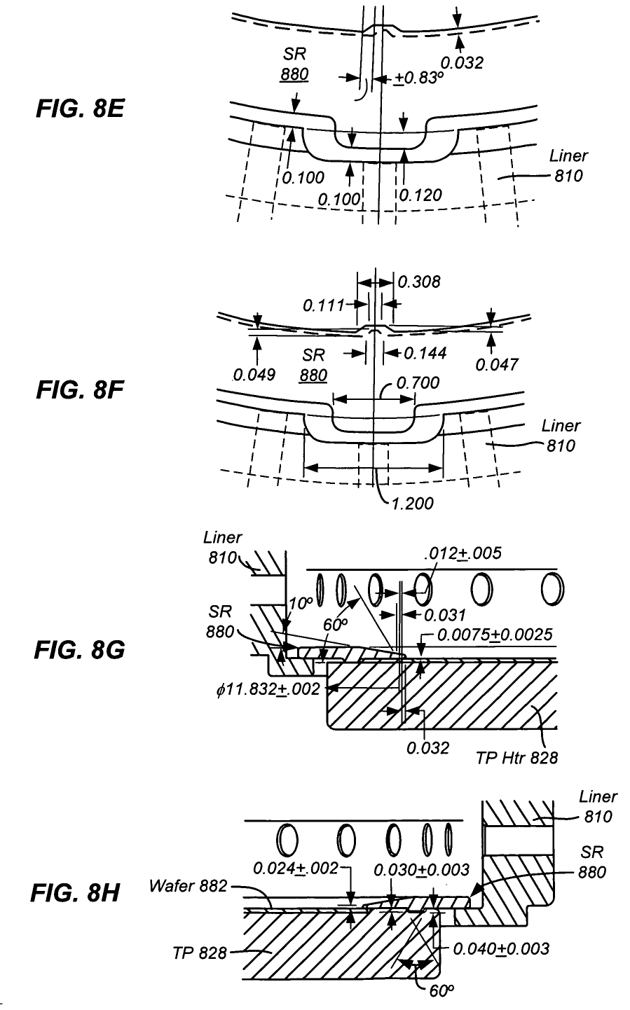

FIG. 8A shows a simplified cross-sectional view of an embodiment of a process kit featuring an embodiment of a shadow ring in accordance with the present invention. FIG. 8B shows a simplified cut-away perspective view of the shadow ring of FIG. 8A. FIG. 8C shows a simplified plan view of the process kit of FIG. 8A. FIG. 8D shows a simplified and enlarged perspective sectional view of the shadow ring of FIG. 8A.

As shown in FIGS. 8A-D, shadow ring 880 includes overhanging portion 880a extending for lateral distance X over the edge of wafer 882 supported on heater/support 828 including embedded electrode 862. Shadow ring 880 is configured such that overhanging portion 880a is separated from the wafer 882 by a vertical distance Y.

The center of the upper surface of heater/support 828 defines recessed heater 828b configured to receive end position wafer 882. A detailed description of one embodiment of a “tight pocket” heater (“TP Htr”) design may be found in nonprovisional U.S. patent application Ser. No. 10/684,054, filed Oct. 10, 2003 and incorporated by reference herein for all purposes.

The edge of the upper surface of heater/support 828 defines recess 828a that is configured to receive vertical tab 880c projecting from the underside of ring 880. Mating between vertical tab 880c and recess 828c helps align shadow ring on heater/support 828.

Heater/support 828 also features tab 880d projecting in the horizontal direction from its edge. Modified pumping liner 810 defines channel 810a configured to receive tab 880d, thereby allowing movement of shadow ring 880 in the vertical direction.

Specifically, wafer 882 is initially loaded onto heater/support 828, where pocket 828b ensures the specific positioning of the wafer thereon. Next, heater/support 828 rises, such that recess 828c engages and mates with vertical tabs 880c on the underside of shadow ring 880, thereby ensuring proper alignment between the shadow ring and the wafer positioned within the pocket.

Once the wafer heater/support has risen to the processing position, gases are flowed into the chamber through an overlying showerhead (not shown), and reactive by-products exhausted through orifices (not shown) in modified pumping liner 810.

Upon completion of deposition, wafer heater/support 828 is lowered, and tab 880d of shadow ring 880 comes to rest on the lip defined by the bottom of vertical channel defined by the pumping liner 810. Once disengaged from shadow ring 880, wafer heater/support continues to lower in order to make the wafer available for transfer to the next processing stage.

The chemical vapor deposition of APF™ and other materials may take place in conjunction with the formation of an energized plasma. The presence of this plasma in the processing chamber can create a sufficient potential difference between the wafer and the overlying shadow ring to give rise to arcing events that can damage the wafer.

Accordingly, embodiments of shadow rings of the present invention should be designed to balance the need to avoid bevel deposition against the need to minimize such arcing events. FIGS. 8E-F show simplified plan views illustrating various dimensions (in inches) of one embodiment of a shadow ring in accordance with the present invention, for use in the deposition of APF™ material upon a 300 mm diameter substrate. FIGS. 8G-H show simplified cross-sectional views illustrating dimensions of the embodiment of the shadow ring of FIGS. 8E-F.

Typically, the deposition of APF™ material involves the application of RF power to the chamber of between about 800-1200 W for a wafer having a diameter of 200 mm, and between about 1400-1800 W for a wafer having a diameter of 300 mm. The lateral overhang distance X may range from between about 0.8-2.0 mm, and the vertical spacing distance Y may be 0.0045″ to +/−0.003″. The precise optimal dimensional ranges may vary for other embodiments of shadow rings configured to inhibit deposition of material on the wafer bevel under different conditions.

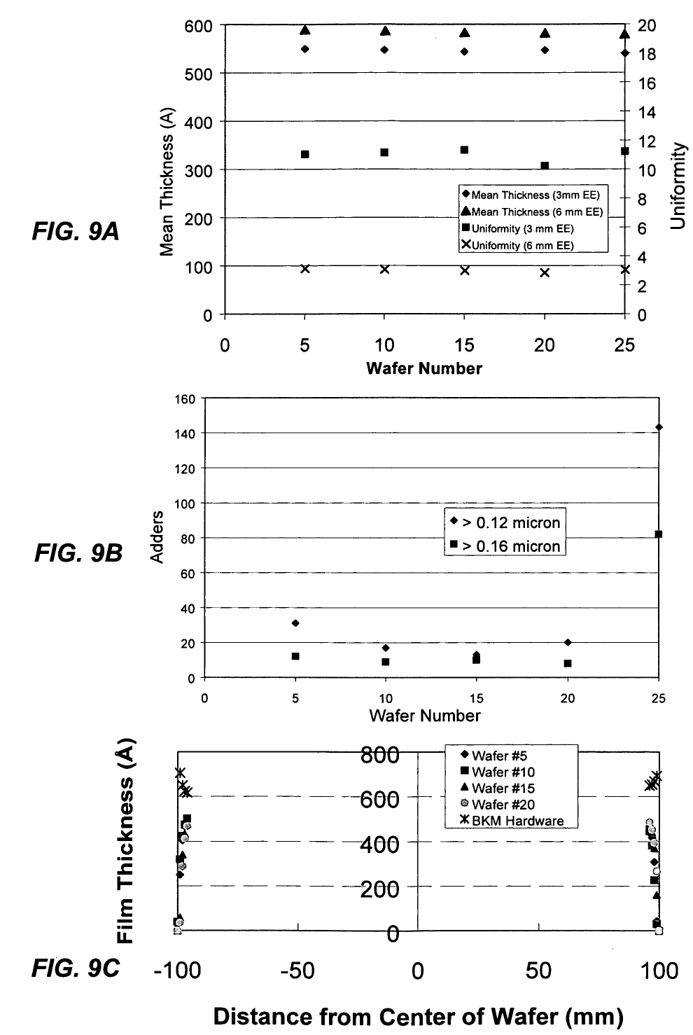

FIG. 9A plots mean thickness and uniformity for a batch of twenty-five wafers bearing a layer of APF™ deposited utilizing an embodiment of a shadow ring in accordance with the present invention. FIG. 9A shows these characteristics of materials deposited utilizing the apparatus of FIG. 9A to be consistent from wafer-to-wafer.

FIG. 9B plots particle contamination adders of two different sizes for the wafer of the batch of FIG. 9A. FIG. 9B shows that use of the shadow ring did not result in substantial contamination of the wafer.

FIG. 9C plots thickness of a deposited film versus distance from the center of the wafer of FIG. 9A. FIG. 9C shows that as compared with deposition equipment for the best known method (BKM) lacking the shadow ring, a reduction in the thickness of material deposited at the wafer edge was observed.

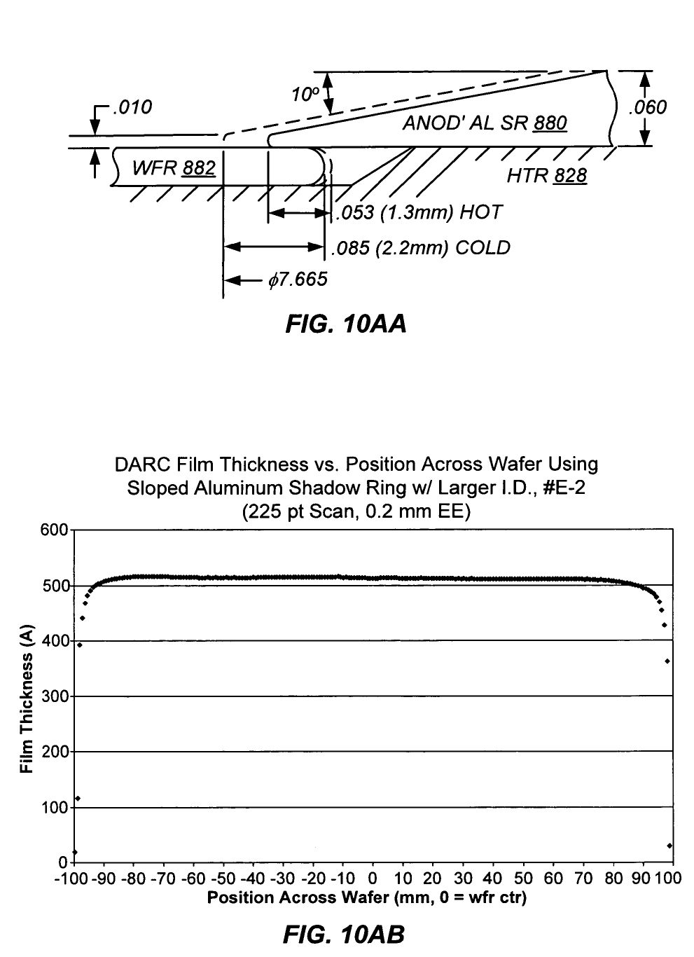

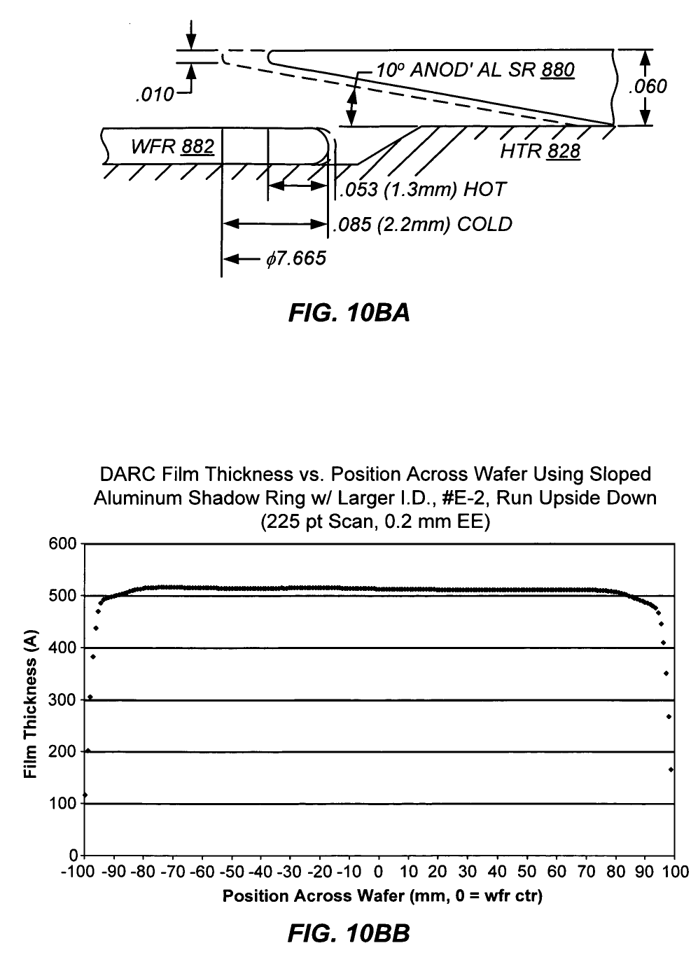

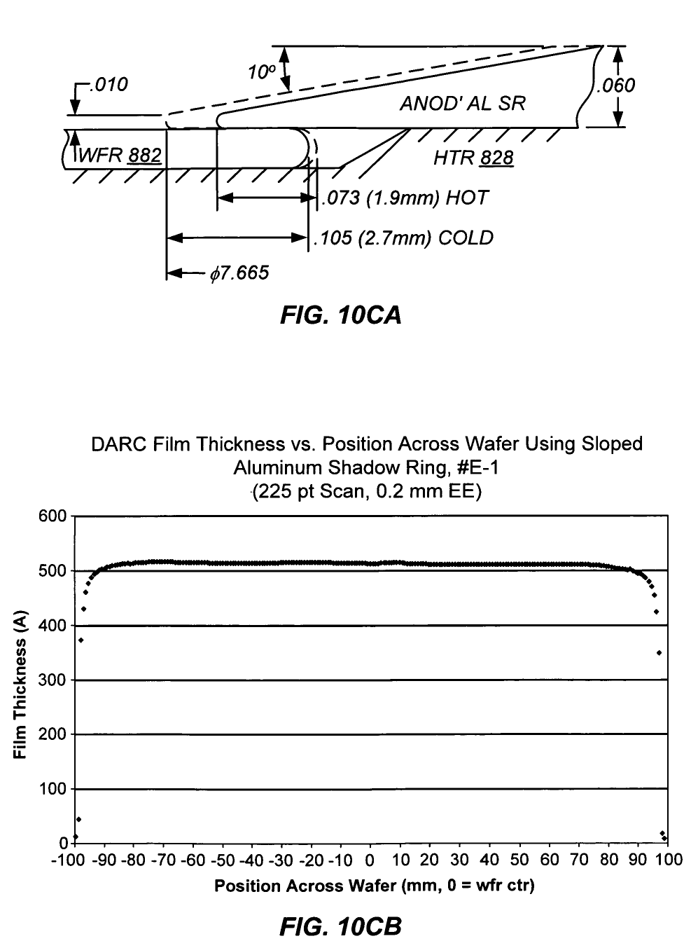

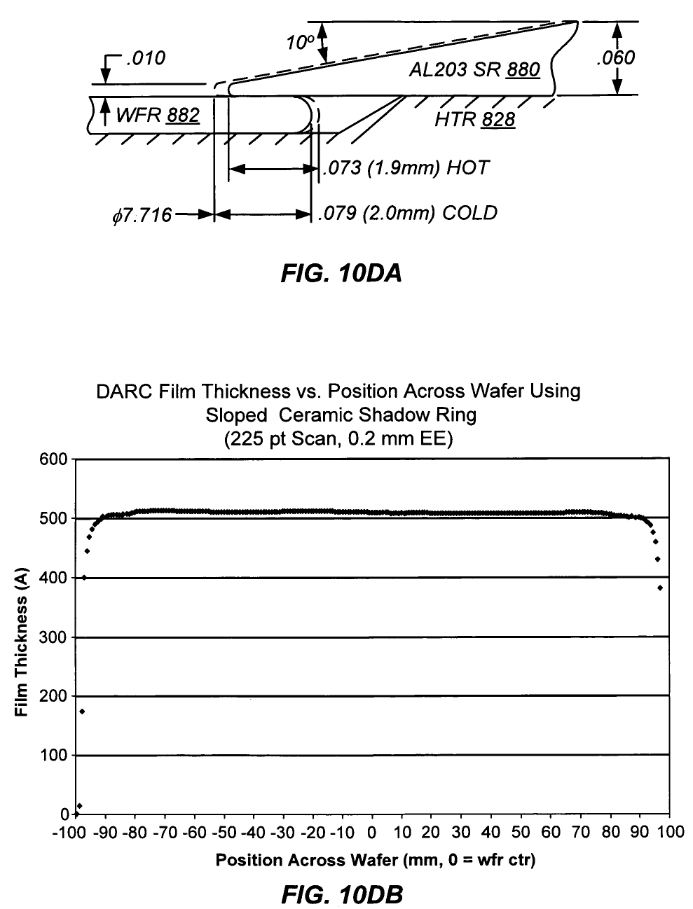

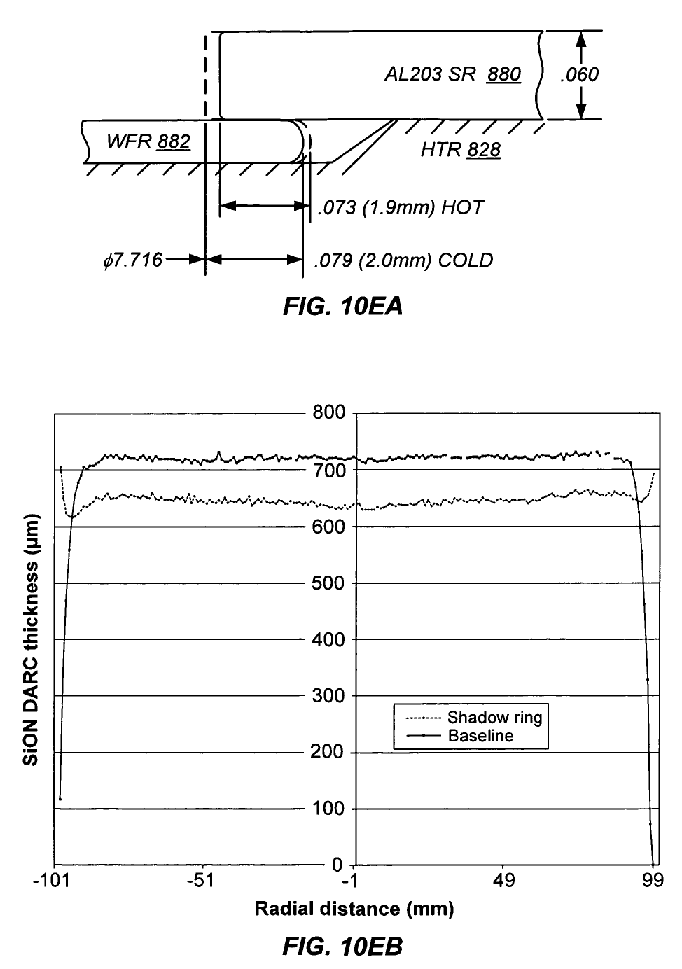

Embodiments of shadow rings in accordance with the present invention may assume a variety of shapes, be constructed from different materials, and maintained at different electrical states. The following TABLE summarizes the results of depositing of a dielectric anti-reflective coating (DARC) of silicon oxynitride upon a 300 mm diameter wafer, utilizing shadow rings exhibiting the physical characteristics shown in simplified cross-section in FIGS. 10AA-10AE.

TABLE
Anod. Al = grounded anodized aluminum
Al₂O₃ = aluminum oxide

| | | Shadow Ring FIG. | | | | |
|---|---|---|---|---|---|---|
| | | 10AA | 10BA | 10CA | 10DA | 10EA |
| X - hot (mil) | | 53 | 53 | 73 | 73 | 73 |
| Distance from wafer center to | | 7716 | 7716 | 7665 | 7665 | 7665 |
| start of overhang - cold (mil) | | | | | | |
| Shadow Ring Composition | | Anod. Al | Anod. Al | Anod Al. | Al₂O₃ | Al₂O₃ |
| Overhang Incline (degrees) | | +10 | −10 | +10 | +10 | +90 |
| Thickness of | −99.8 | 20 | 116 | 15 | 0 | 0 |
| SiON DARC | −98.9 | 116 | 202 | 46 | 14 | 117 |
| Deposited at a | −98.0 | 392 | 304 | 373 | 174 | 338 |
| Radial Distance | −97.1 | 441 | 382 | 431 | 399 | 469 |
| of (mm): | −96.2 | 467 | 437 | 461 | 445 | 559 |
| | +96.2 | 454 | 408 | 424 | 461 | 463 |
| | +97.1 | 426 | 350 | 349 | 436 | 328 |
| | +98.0 | 362 | 267 | 20 | 382 | 72 |
| | +98.9 | 20 | 166 | 11 | 56 | 0 |
| | +99.8 | 0 | 0 | 0 | 11 | 0 |

| | | | | | |
|---|---|---|---|---|---|
| Line Scan Mean Thickness (Å) | 508 | 508 | 508 | 504 | 714 |
| (3 mm Edge Exclusion) | | | | | |
| Std Dev./Mean (%) | 2.1 | 3.6 | 3.1 | 2.3 | 4.7 |
| (3 mm Edge Exclusion) | | | | | |
| (Max-Min)/2x Mean (%) | 49.4 | 51.7 | 50.5 | 51.6 | 53.5 |
| (All Points) | | | | | |
| (Max-Min)/2x Mean (%) | 8.8 | 16.3 | 16.3 | 11.0 | 18.8 |
| (3 mm Edge Exclusion) | | | | | |

The DARC material was formed by plasma-assisted chemical vapor deposition involving silane, N₂O, and helium gases. FIGS. 10AB-10EB plot thickness of deposited material versus radial distance for the shadow rings of FIGS. 10AA-EA, respectively.

The TABLE and FIGS. 10AB-10EB reveal that the highest mean uniformity of the deposited DARC layer was achieved with the inclined anodized aluminum shadow ring of FIG. 10AA, which extended the shortest distance (53 mil) over the wafer periphery. The simple experiment of inverting this shadow ring design (FIG. 10BA) resulted in increased nonuniformity of deposited material.

Utilizing an inclined anodized aluminum shadow ring modified to extend further over the wafer periphery (FIG. 10CA), resulted in a deposited film having less uniformity than one deposited utilizing the shadow ring of FIG. 10AA. This was believed to be due to the loss of distance available for deposition from the edge of the shadow ring to the 3 mm edge exclusion boundary. Specifically, material formed within this “lost” distance utilizing the shortened shadow ring, may allow the deposited layer to approach mean thickness values prior to reaching the 3 mm edge exclusion boundary, thereby enhancing thickness uniformity.

The composition and electrical state of the shadow ring may also affect the quality of deposition of material. Deposition utilizing each of the shadow rings of FIGS. 10AA-10CA occurred utilizing a shadow ring comprising conductive anodized aluminum in electrical communication with ground. By contrast, deposition utilizing the shadow rings of FIGS. 10D-E occurred utilizing a shadow ring comprising a dielectric material—aluminum oxide (Al₂O₃).

While embodiments of shadow rings in accordance with the present invention may comprise conducting or dielectric materials, a grounded shadow ring bearing at least an electrically conducting surface may improve uniformity of deposited material. Specifically, such a grounded conducting shadow ring would not substantially alter the shape of the electromagnetic field overlying the wafer surface. In this manner, a grounded conducting shadow ring could serve as a purely physical barrier to deposition of material on wafer bevel portions. By contrast, a shadow ring comprising dielectric material could alter the shape of the electromagnetic field overlying edge regions of the wafer, thereby affecting uniformity of the plasma and the material deposited therefrom.

Embodiments of shadow rings in accordance with the present invention may be constructed from a variety of materials. Examples of such materials include aluminum, anodized aluminum, aluminum oxide, aluminum nitride, quartz, and other materials such as alloys of nickel such as ICONEL™ and Hasteelloy. In accordance with certain embodiments, a shadow ring may comprise a composite of materials, for example a dielectric core bearing a conductive surface such as nickel formed by electroplating and/or flame spraying.

Finally, use of an extended aluminum oxide shadow ring having a blunt, rather than inclined, end (FIG. 10EA) resulted in the lowest value of thickness uniformity. This is likely attributable to the effect of the blunt end obstructing processing gases from reaching non-shadowed wafer regions proximate to the edge of the shadow ring. The inclined edge of the shadow ring designs of FIGS. 10AA and 10CA enhances the flow of gases to such non-shadowed regions, thereby promoting deposition in those regions of material having a thickness comparable other non-shadowed regions.

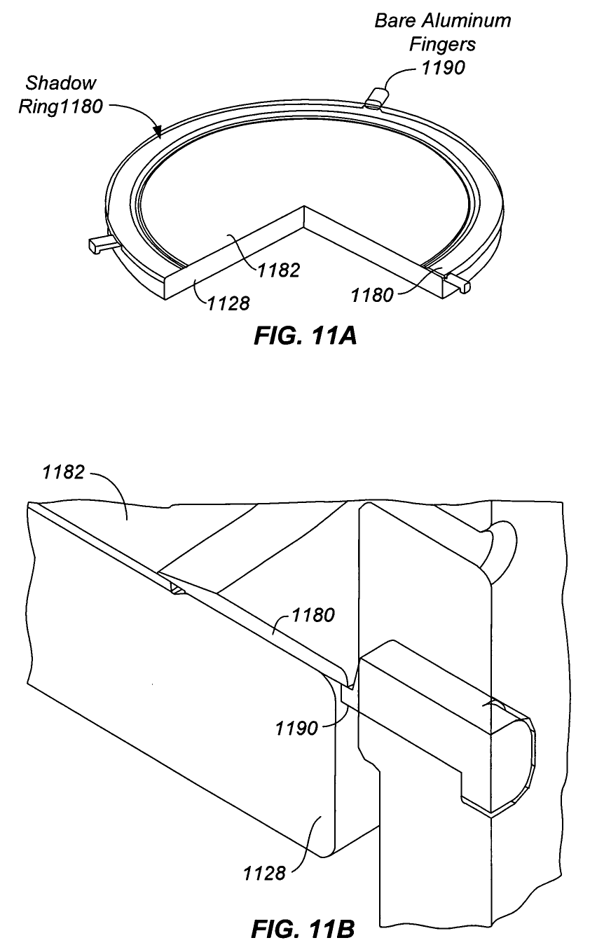

Embodiments in accordance with the present invention are not limited to the specific support mechanism shown in FIGS. 8A-D. FIG. 11A shows a simplified perspective cut-away view of another alternative embodiment of a shadow ring in accordance with the present invention, positioned within a pumping liner. FIG. 11B shows an enlarged simplified perspective cut-away view of the shadow ring of FIG. 11A. The design of FIGS. 11A-B is similar to that shown in FIGS. 8A-H, except that when not in use, shadow ring 1180 is supported by bare aluminum fingers 1190 rather than by a lip of a vertical channel present in the pumping liner.

Embodiments of shadow rings in accordance with the present invention may include other types of features. For example, as described above, the wafer heater heater/support includes an embedded electrode. This embedded electrode is responsible for generating an electrical field that imparts directionality to charged species present within the reaction chamber.

As also shown in FIGS. 3 and 8A, the embedded electrode extends for a distance beyond the expected edge of the supported wafer. This is because the electric field associated with the electrode edge does not exhibit planar shape and intensity. By extending the electrode, these field nonuniformities associated with the electrode edge are moved beyond the wafer edge, thereby ensuring more uniformity of deposited materials.

As further shown in FIG. 8A, a portion of the shadow ring in accordance with an embodiment of the present invention also overlies the embedded electrode, and its permeability can undesirably alter the shape and intensity of the electric field generated therefrom.

Therefore, an alternative embodiment of a shadow ring in accordance with the present invention features gaps between the overhang portion and the edge portion in order to help maintain uniformity of the electric field over the wafer edge.

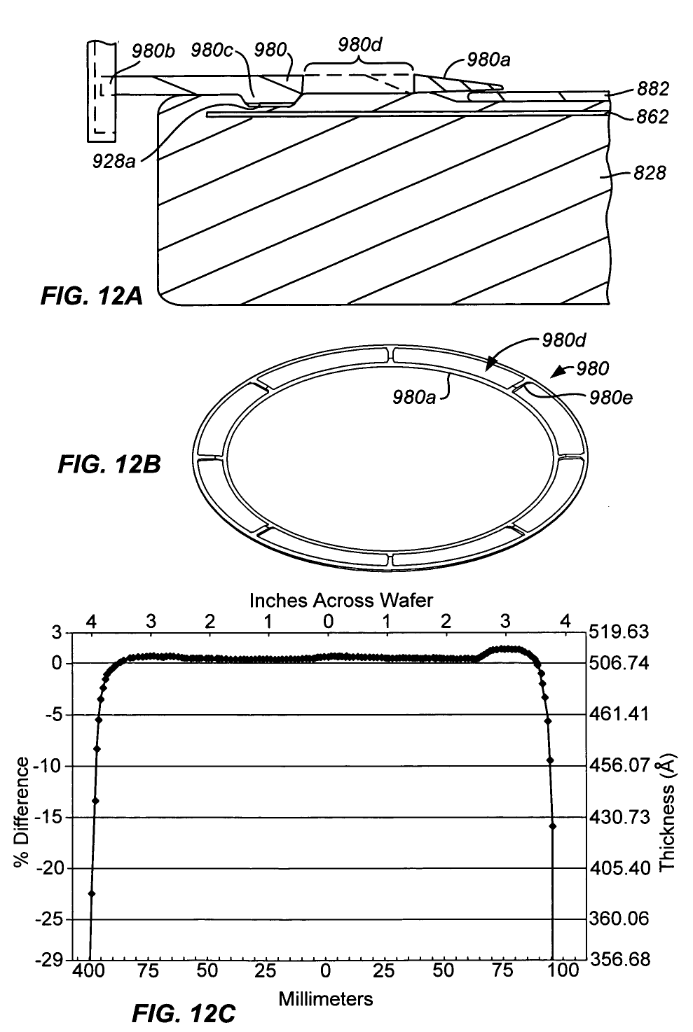

FIG. 12A shows a simplified cross-sectional view of an embodiment of such a “webbed” shadow ring in accordance with the present invention. FIG. 12B shows a perspective view of the shadow ring of FIG. 12A.

Webbed shadow ring 980 is similar to that shown in FIGS. 8A-D, and features horizontal tabs 980a and vertical tabs 980b configured to mate with recessed features of pumping liner 910 and wafer support 928, respectively. However, webbed shadow ring 980 features gaps 980c between overhang portion 980d and edge portions 980e, with portions 980d and 980e maintained in physical contact by intervening spar portions 980f.

FIG. 12C plots thickness of deposited material versus radial distance for a shadow ring of FIG. 12A. The presence of gaps 980c help to ensure the uniformity of the magnetic field at edge regions of the wafer, and hence the uniformity of material deposited in non-shadowed edge regions.

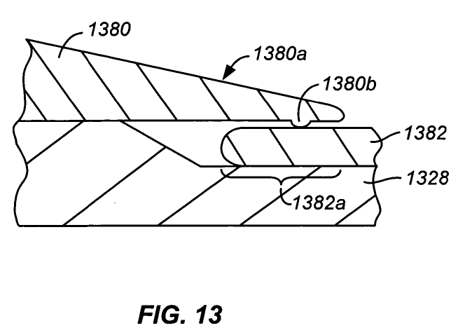

FIG. 13 shows a simplified cross-sectional view of yet another embodiment of a shadow ring design in accordance with the present invention. Specifically, overhanging portion 1380a of shadow ring 1380 features one or more projections 1380b on its underside. Projections 1380b make physical contact with the underlying wafer 1382.

Use of a shadow ring of the type shown in FIG. 13 may enhance processing according to a number of possible mechanisms. The projection may serve as a physical spacer, ensuring that the narrow but minimum required spacing is present between the overhang portion of the shadow ring and the underlying wafer. In this role as a physical spacer, the projection may thus allow for relaxation of tolerance limits that must otherwise take into account inherent variation in wafer and ring thickness profiles, thereby allowing even closer spacing of the shadow ring with the wafer.

The presence of the projection may also establish electrical contact between the shadow ring and the underlying wafer. By maintaining the shadow ring and the wafer at the same electrical potential, unwanted arcing events between the shadow ring and the wafer giving rise to processing nonuniformity may be reduced or eliminated.

Projection 1380b is designed to contact substrate 1382 only in excluded edge regions 1382a. Thus any possible contamination arising from physical contact between the shadow ring 1380 and the underlying wafer 1382 should not affect wafer yield.

In accordance with one embodiment of the present invention, a shadow ring for deposition of material on a 300 mm wafer comprised AlN having three projections of a diameter of 0.05″+/−0.01″ and a height of 0.0045″, with a tolerance between +0.0002″ and −0.0001″. An embodiment of a shadow ring in accordance with the present invention would feature at least three projections, with a greater number possible.

Edge Purge Heater

The processing kit described above may be modified in accordance with embodiments of the present invention to feature an edge purge heater feature. This involves a heater structure modified to flow purge gases to edge portions of the substrate in order to inhibit deposition of material on bevel portions.

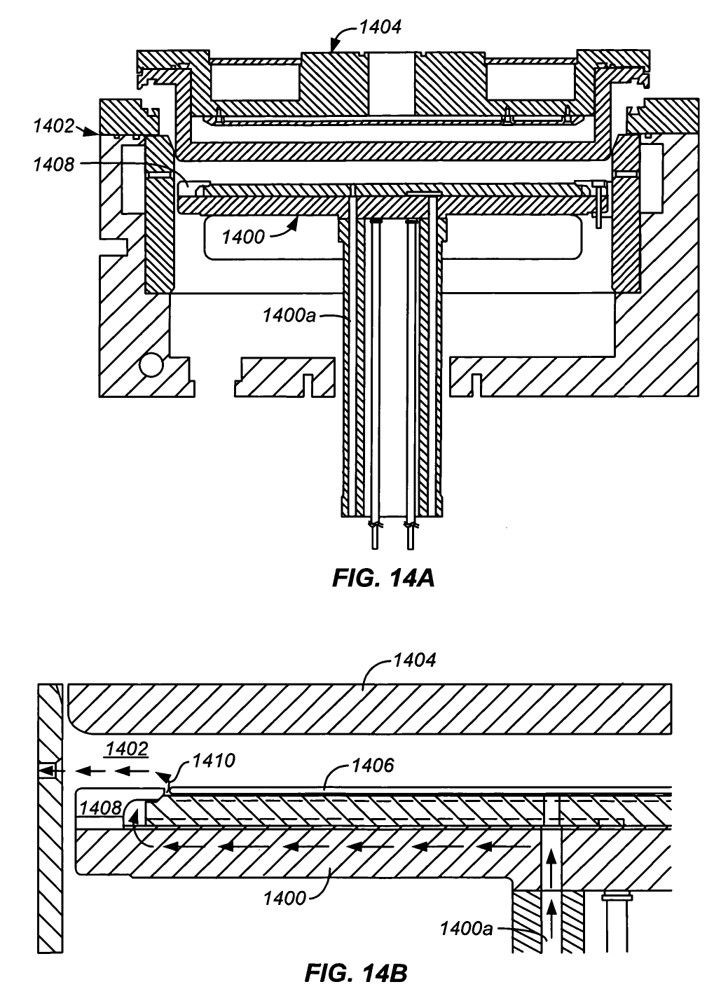

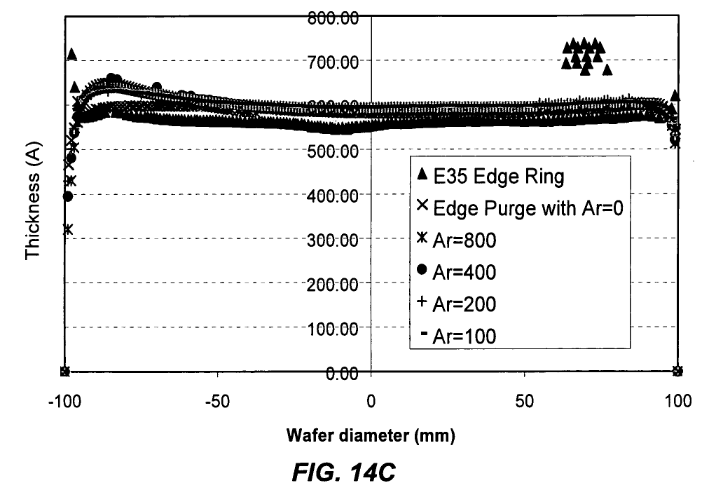

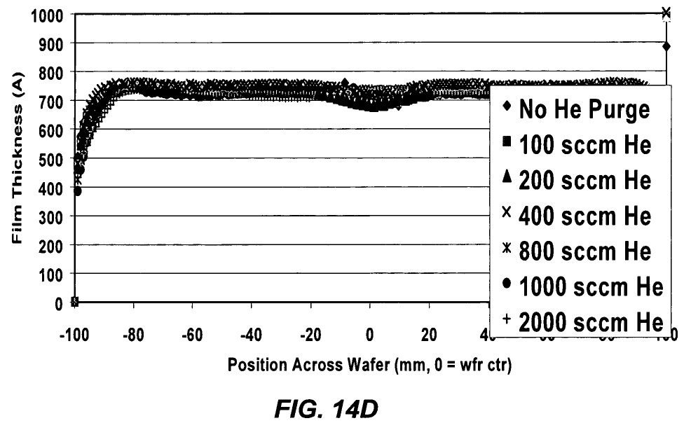

FIG. 14A shows a simplified cross-sectional view of a heater featuring an edge purge gas system in accordance with an embodiment of the present invention. FIG. 14B shows a simplified enlarged cross-sectional view of the heater of FIG. 14A.

FIGS. 14A-B show heater/support 1400 located in chamber 1402 underneath gas distribution showerhead 1404. Substrate 1406 is positioned upon support 1400 within a pocket defined by a surrounding edge ring 1408. Heater 1400 is configured to include channel 1400a for flowing purge gases 1410 to the base of edge ring 1408, between edge ring 1408 and the edge of the substrate. By directing an outward flow of purge gas along the wafer edge, the flow of processing gas to edge/bevel regions of the substrate is impeded, and deposition of materials in these edge regions lessened or eliminated.

FIG. 14C plots thickness of deposited DARC material versus position on a wafer supported by the heater structure of FIG. 14A, for various flow rates of nitrogen purge gas to the edge ring. FIG. 14D plots thickness of deposited DARC material versus position on a wafer supported by the heater structure of FIG. 14A, for various flow rates of helium purge gas to the edge ring.

While the above description has focused upon use of the referenced techniques to reduce deposition of a layer of silicon oxynitride DARC or APF™ on the bevel of a wafer, embodiments in accordance with the present invention are not limited to this particular application. For example, films exhibiting a low dielectric constant (K) have found increasing use in such applications as shallow trench isolation (STI), pre-metal dielectric (PMD), and inter-metal dielectric (IMD).

The formation of such low K films may involve the deposition of silicon oxide incorporating substantial amounts of carbon. One such low K film is known as BLACK DIAMOND™ sold by Applied Materials, Inc. of Santa Clara, Calif.

Another type of low K film features carbon-containing molecules as porogens in as-deposited form. Annealing subsequent to deposition liberates the porogens, leaving behind nanopores which reduce the dielectric constant of the film. One example of such a nanoporous film is described in U.S. Pat. No. 6,541,367, incorporated by reference herein for all purposes.

Enhanced deposition on the wafer bevel has been observed during the plasma-assisted CVD formation processes for both of these films. Embodiments of methods and apparatuses in accordance with the present invention may therefore be utilized to reduce bevel deposition of these and other types of carbon-containing low K films.

While the above is a complete description of specific embodiments of the present invention, various modifications, variations, and alternatives may be employed. These equivalents and alternatives are included within the scope of the present invention. Therefore, the scope of this invention is not limited to the embodiments described, but is defined by the following claims and their full scope of equivalents.

1. A method of chemical vapor depositing a material upon a workpiece, the method comprising:
positioning a shadow ring featuring an inclined overhang portion overlying edge regions of a substrate supported within a processing chamber, the shadow ring extending a distance of between about 0.8-2.0 mm over the edge regions and separated from the edge regions by a gap of about 0.0045″+/−0.003″;
flowing a processing gas to the chamber; and
applying energy to the chamber to generate a plasma therein, such that reaction of the processing gases results in deposition of a material outside the edge regions.

2. The method of claim 1 wherein:
positioning the shadow ring comprises positioning the shadow ring over a workpiece having a diameter of 200 mm;
flowing the processing gas comprises flowing a hydrocarbon having a general formula of CxHy, where x is between 2-4 and y is between 2-10; and
applying energy comprises applying RF energy having a power of between about 800-1200 W to deposit an amorphous carbon material.

3. The method of claim 1 wherein:
positioning the shadow ring comprises positioning the shadow ring over a workpiece having a diameter of 300 mm;
flowing the processing gas comprises flowing a hydrocarbon having a general formula of CxHy, where x is between 2-4 and y is between 2-10; and
applying energy comprises applying RF energy having a power of between about 1400-1800 W to deposit an amorphous carbon material.

4. The method of claim 1 wherein:
flowing the processing gas comprises flowing a nitrogen-containing gas; and
applying the energy results in the deposition of a dielectric anti-reflective coating (DARC) material comprising silicon oxynitride.

5. The method of claim 1 wherein:
flowing the processing gas comprises flowing a carbon-containing processing gas; and
applying the energy comprises results in the deposition of a carbon-containing silicon oxide material.

6. The method of claim 5 wherein:
flowing the carbon-containing processing gas comprises flowing a porogen; and
the method further comprises annealing the carbon-containing silicon oxide to liberate the porogen.

7. The method of claim 1 wherein the shadow ring is in physical contact in at least one location with an edge exclusion region of the workpiece.

8. The method of claim 1 wherein the shadow ring defines gaps to promote uniformity of an electric field overlying the substrate and produced by an embedded substrate support electrode.

9. A method of chemical vapor depositing a dielectric film, the method comprising:
positioning a substrate upon a support within a processing chamber;
flowing a purge gas through the support to edge regions of the substrate;
flowing a processing gas to the chamber; and
applying energy to the chamber to generate a plasma therein, such that the purge gas flow impedes a flow of processing gas to the edge regions and inhibits deposition of a dielectric material in the edge regions.

10. The method of claim 9 wherein flowing the purge gas comprises flowing at least one of helium, argon, and nitrogen.

11. The method of claim 9 wherein flowing the processing gas comprises flowing a carbon-containing material.

12. An apparatus for depositing dielectric material on a workpiece, the apparatus comprising:
a vertically moveable substrate support positioned within a processing chamber;
an energy source configured to apply energy to the processing chamber in order to generate a plasma therein;
a pumping liner defining an exhaust orifice and a vertical channel;
a shadow ring comprising an overhang portion configured to extend a distance of about 0.8-2.0 mm over the edge regions and be separated from the edge regions by a gap of about 0.0045″+/−0.003″ when the substrate support rises to engage the shadow ring.

13. The apparatus of claim 12 wherein the substrate support defines a recess in an upper surface, and the shadow ring comprises a projection configured to mate with the recess.

14. The apparatus of claim 12 wherein the shadow ring defines gaps to promote uniformity of an electric field overlying the substrate and produced by a substrate support electrode.

15. The apparatus of claim 12 wherein the shadow ring comprises a dielectric material.

16. The apparatus of claim 15 wherein the dielectric material comprises at least one of aluminum oxide, aluminum nitride, and quartz.

17. The apparatus of claim 12 wherein the shadow ring comprises an electrically conducting material.

18. The apparatus of claim 17 wherein the shadow ring is grounded.

19. The apparatus of claim 18 wherein the shadow ring comprises a dielectric core bearing an electrically conducting surface.

20. The apparatus of claim 19 wherein the electrically conducting surface comprises one of an electroplated and a flame sprayed metal.

21. The apparatus of claim 12 wherein a lower surface of the overhang portion comprises a projection configured to contact an edge exclusion region of the workpiece.

22. The apparatus of claim 12 wherein an upper surface of the overhang portion comprises an incline configured to direct a flow of processing gases toward the substrate.
